(19) United States
(12) Patent Application Publication
(10) Pub. No.: US 2025/0331130 A1
(43) Pub. Date: Oct. 23, 2025

(54) JOINT, SERVER, AND COMPUTING SYSTEM

(71) Applicant: Fulian Precisin Electronics (Tianjin) Co., Ltd., Tianjin (CN)

(72) Inventors: CHANG-JU WU, New Taipei (TW); Chih-Min Lin, New Taipei (TW)

(21) Appl. No.: 18/937,404

(22) Filed: Nov. 5, 2024

(30) Foreign Application Priority Data
Apr. 18, 2024 (CN) 202410470408.9

(51) Int. Cl. H05K 7/20; G06F 1/18; G06F 1/20

(52) U.S. Cl. CPC H05K 7/20272; G06F 1/181; G06F 1/20; H05K 7/20781

(57) ABSTRACT

A joint for cutting coolant circuit in a server comprises a first shell, a second shell, and a folding mechanism. The first shell has a tunnel and a seal ring in the tunnel. The second shell has a first tube section and a second tube section. The folding mechanism can move the second shell. The first tube section and the second tube section are movably inserted in the tunnel, an outer diameter of the first tube section is larger than an outer diameter of the second tube section, when the second shell is on a first position, the seal ring surrounds the first tube section and is compressed by the first tube section, when the second shell is on a second position, the seal ring surrounds the second tube section and is uncompressed. A server and a computing system with the joint are also disclosed.

### FIELD

The disclosure herein generally relates to information computing systems, and more particularly relates to a joint, a server, and a computing system.

### BACKGROUND

A server is installed in a rack, a plug connector is locked on a backside of the server and is connected to a plug on the rack. Coolant can flow through the plug of the server and the plug of the rack to cool the server. The coolant may leak from the connection between the plug of the server and the plug of the rack, and causing damages to the server.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is an isometric view of an embodiment of a joint according to the present disclosure, showing the joint and a plug are connected.

FIG. 2 is an explored view of the joint shown in FIG. 1.

FIG. 3 is a side section view of the joint and the plug in FIG. 1, showing the joint and the plug are connected.

FIG. 4 is a side section view of the joint and the plug in FIG. 3, showing the joint and the plug are disconnected.

FIG. 5 is an isometric view of a folding mechanism shown in FIG. 1.

FIG. 6 is an isometric view of a first shell shown in FIG. 1.

FIG. 7 is an isometric view of a second shell shown in FIG. 1.

FIG. 8 is an embodiment of a server according to the present disclosure.

FIG. 9 is an embodiment of a computing system according to the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, baffle structures, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The present disclosure, including the accompanying drawings, is illustrated by way of examples and not by way of limitation. Several definitions that apply throughout this disclosure will now be presented. It should be noted that references to “an” or “one” embodiment in this disclosure are not necessarily to the same embodiment, and such references mean “at least one”.

The term “comprising” means “including, but not necessarily limited to;” it specifically indicates open-ended inclusion or membership in a so-described combination, group, series, and the like.

Without a given definition otherwise, all terms used have the same meaning as commonly understood by those skilled in the art. The terms used herein in the description of the present disclosure are for the purpose of describing specific embodiments only, and are not intended to limit the present disclosure.

Nowadays for computing systems, when a server is installed in a rack, a plug connector behind the server is connected to a plug on the rack, so that the rack can provide coolant to the server to cool the server. However, there is a risk of coolant leakage, and when the coolant leak in the server, if the coolant circuit is not cut in time, a large amount of coolant will enter the server, causing damage to the server.

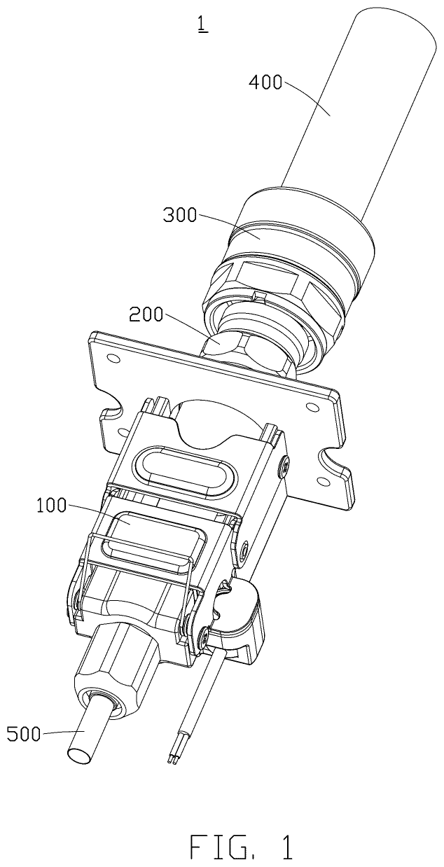

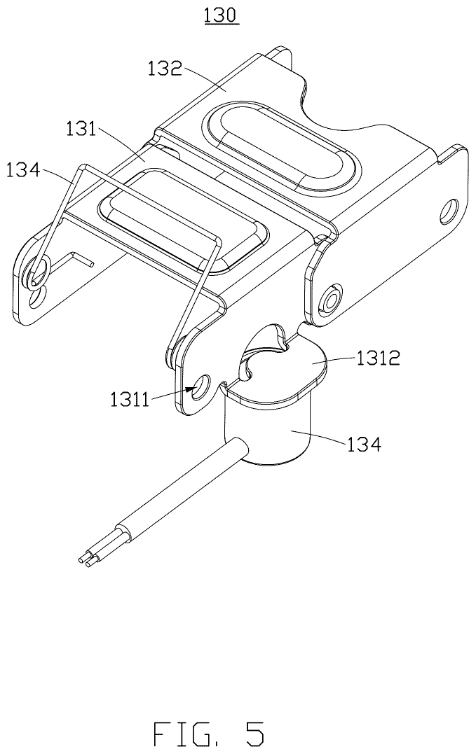

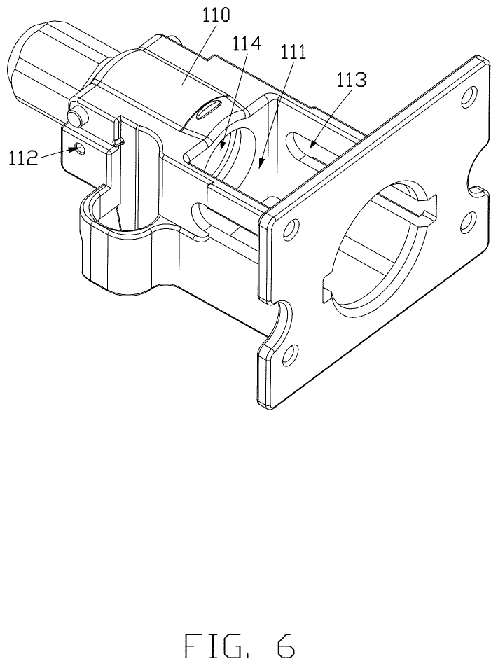

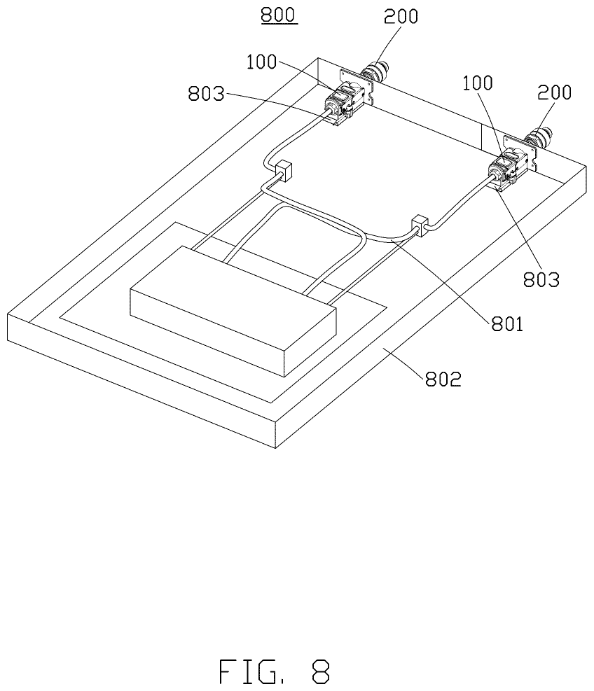

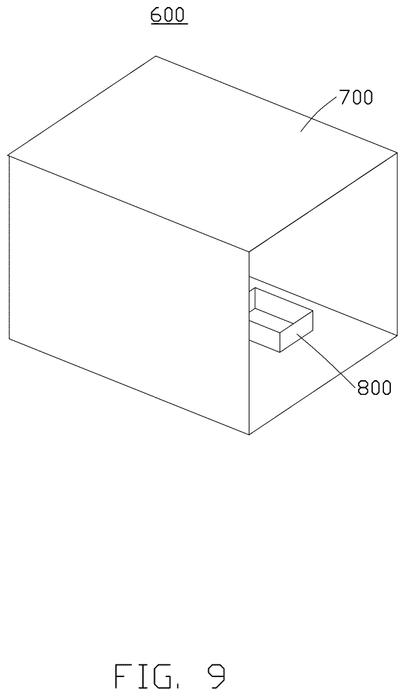

As shown in FIG. 1 to FIG. 9, a computing system 600 in an embodiment includes a rack 700 and a plurality of servers 800. The plurality of servers 800 can be installed into the rack 700 in layers. The rack 700 includes a plurality of plugs 300, and there is at least one plug 300 in each layer. Each plug 300 is connected to a first tube 400 of the rack 700. Each server 800 has a plug connector 200 in the back. When one of the plurality of servers 800 is installed into the rack 700, the plug connector 200 needs to be connected to the plug in the same layer, so that the rack 700 can provide coolant to the server 800 to cool the server 800. Usually, there are two plugs 300 in each layer in the rack 700, and there are two plug connectors 200 in the back of each server 800, when the server 800 is installed into the rack 700, the two plug connectors 200 are connected to the two plugs 300 one-to-one, so that the coolant can be circulated between the server 800 and the rack 700.

However, there is a risk of coolant leakage, and when the coolant leak in the server 800, if the coolant circuit 801 in the server 800 is not cut in time, the coolant will enter the server 800, causing damage to the server 800.

In some embodiments, to solve the problem mentioned above, the server 800 in an embodiment includes a chassis 802, two sensors 803, and two joints 100 with two plug connectors 200. The joints 100 and the sensors 803 are located on the chassis 802. Each sensor 803 is configured for sensing the coolant leakage in the server 800, if there is any coolant leakage, the joints 100 disconnect the plug connectors 200 with the plug 300, to cut off the coolant circuit 801 for protecting the server 800.

As shown in FIG. 1 to FIG. 7, in some embodiments, each joint 100 in an embodiment includes a first shell 110, a second shell 120, and folding mechanism 130. The first shell 110 is connected to a second tube 500 of the coolant circuit 801 in the server 800. The second shell 120 is placed on the first shell 110 and is movable in a first direction X between a first position and a second position. The second shell 120 is used for connecting the plug connector 200. The folding mechanism 130 is connected to the first shell 110 and the second shell 120, and the folding mechanism 130 is used for moving the second shell 120 in the first direction X.

The folding mechanism 130 includes a first folding piece 131, a second folding piece 132, a switch 133, and a spring 134. The first folding piece 131 is rotatably connected to the first shell 110, the second folding piece 132 is rotatably connected to the second shell 120, and the first folding piece 131 is rotatably connected to the second folding piece 132. The switch 133 is placed on the first shell 110, the switch 133 has a first condition and a second condition. When the switch 133 is in the first condition, the first folding piece 131 and the second folding piece 132 are unfolded, the second shell 120 is kept on the first position and able to connect the plug connector 200 to the plug 300. When the switch 133 is in the second condition, the first folding piece 131 and the second folding piece 132 are folded, the second shell 120 is moved to the second position and the plug connector 200 is disconnected from the plug 300, to cut off the connection between the coolant circuit 801 and the rack 700.

The first folding piece 131 has two first holes 1311, the first shell 110 has two second holes 112, a pin (not shown in Figs) extends through the first holes 1311 and the second holes 112, to rotatably connect the first folding piece 131 and the first shell 110. The connection between the first folding piece 131 and the second folding piece 132 and the connection between the second folding piece 132 and the second shell 120 are the same structure.

The spring 134 is located between the second folding piece 132 and the first

shell 110. When the switch 133 is in the first condition, the folding mechanism 130 is kept unfolded, and the spring 134 is compressed. When the switch 133 is in the second condition, the first folding piece 131 and the second folding piece 132 are released, so the spring 134 is released to rotate the first folding piece 131, letting the first folding piece 131 and the second folding piece 132 rotate close to each other, so to fold the first folding piece 131 and the second folding piece 132.

In some embodiments, the switch 133 is an electromagnet switch, the first folding piece 131 has a permanent magnet 1312. The permanent magnet 1312 is located on the first folding piece 131. When the switch 133 is in the first condition, the electromagnet switch is powered off, so the electromagnet within attracts the permanent magnet 1312, so the first folding piece 131 and the second folding piece 132 rotate away from each other, letting the first folding piece 131 and the second folding piece 132 be unfolded, so the second shell 120 is on the first position to connect the plug connector 200 to the plug 300.

When the switch 133 is in the second condition, the electromagnet switch is powered on, the electromagnet within is demagnetized and releases the permanent magnet 1312, so the spring 134 is released to rotate the first folding piece 131, letting the first folding piece 131 and the second folding piece 132 rotate close to each other to fold, then the second shell 120 is on the second position to disconnect the plug connector 200 to the plug 300.

Furthermore, the electromagnet switch (the switch 133) has a coil. The coil is

wrapped around an electromagnet. When the coil is powered on, the coil generates magnetic poles, and the magnetic poles of the coil are opposite to the magnetic poles of the electromagnet, so the magnetism of the electromagnet is weakened by the coil, to demagnetizing the electromagnet and release the permanent magnet 1312.

For another example, the electromagnet switch (the switch 133) has a heater to heat the electromagnet. When the electromagnet is heated to a certain temperature, the magnetism of the electromagnet will disappear, so to demagnetize the electromagnet and release the permanent magnet 1312.

In some embodiments, the first shell 110 defines two sliding grooves 113 on both sides. The second shell 120 has two protrusions 121 on both sides. Each of the two protrusions 121 is slidably placed in each of the two sliding grooves 61, for guiding the second shell 120 and the plug connector 200 moving in the first direction X.

Furthermore, the shape of the protrusion 121 is not round, so the protrusion 121 cannot rotate in the sliding groove 113, to limit the rotation of the second shell 120.

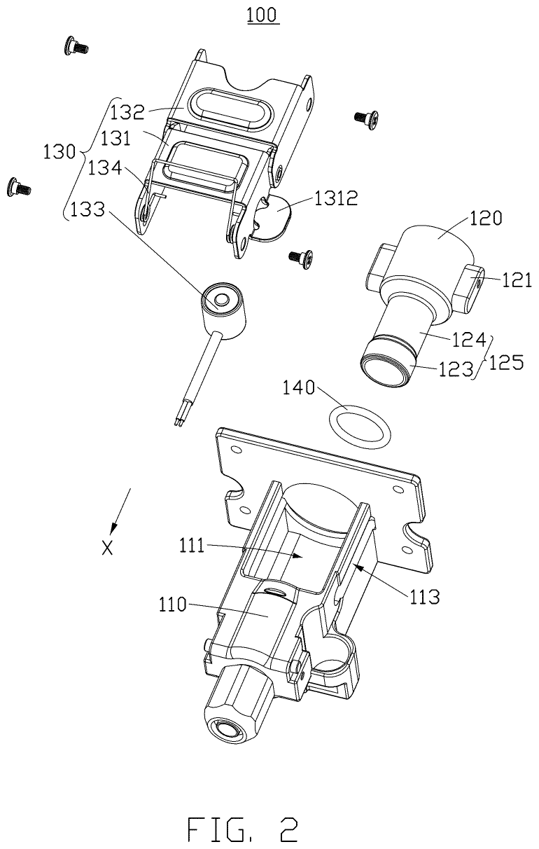

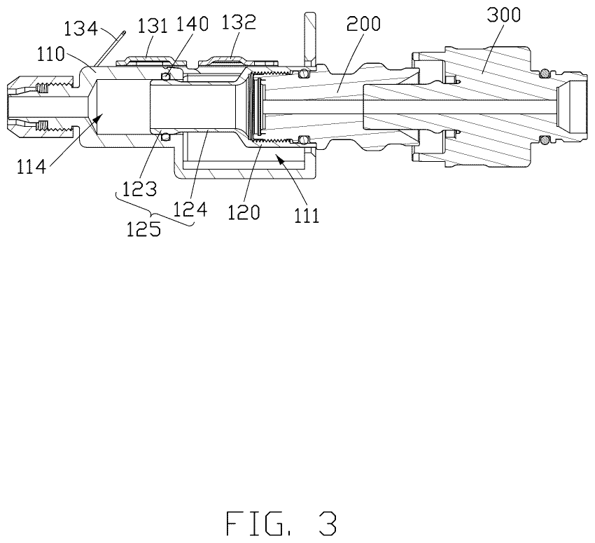

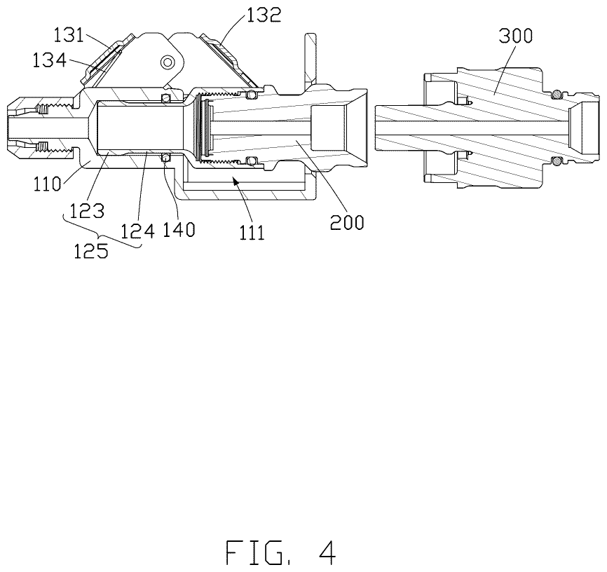

In some embodiments, as shown in FIG. 2, FIG. 3 and FIG. 4, the first shell 110 has a cavity 111 and a tunnel 114, the cavity 111 and the tunnel 114 are used for accommodating the second shell 120, and the tunnel 114 is connected to the second tube 500 of the coolant circuit 801. The second shell 120 has a tube part 125, and the tube part 125 has a first tube section 123 and a second tube section 124. The outer diameter of the first tube section 123 is larger than the outer diameter of the second tube section 124, and the outer diameter of the first tube section 123 is equal to the inner diameter of the tunnel 114, the first tube section 123 is always in the tunnel 114. There is a seal ring 140 in the tunnel 114, when the second shell 120 is on the first position, the seal ring 140 surrounds the first tube section 123, the first tube section 123 contacts and compresses the seal ring 140, and the coolant flows in the tube part 125 and the tunnel 114, the seal ring 140 makes sure that the coolant will not flow out into the cavity 111. When the second shell 120 is on the second position, the seal ring 140 surrounds the second tube section 124, and the seal ring 140 does not contact the second tube section 124, so the seal ring 140 is uncompressed, to decrease friction between the seal ring 140 and the second tube section 124, so the second shell 120 can move faster to cut off the coolant faster.

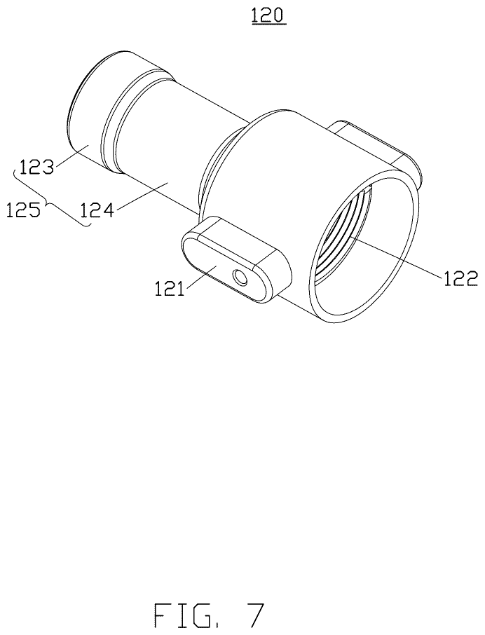

In some embodiments, as shown in FIG. 3, FIG. 4 and FIG. 7, the second shell 120 has an internal thread 122, the plug connector 200 has an external thread, the internal thread 122 is screwed with the external thread to connect the plug connector 200 and the second shell 120.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims.

What is claimed is:

1. A joint comprising:
a first shell defining a tunnel and the first shell comprising a seal ring in the tunnel;
a second shell movably positioned on the first shell, the second shell comprising a first tube section and a second tube section; and
a folding mechanism connected to the first shell and the second shell, the folding mechanism configured for moving the second shell between a first position and a second position;
wherein the first tube section and the second tube section are movably inserted in the tunnel, an outer diameter of the first tube section is larger than an outer diameter of the second tube section; when the second shell is moved to the first position, the seal ring surrounds the first tube section and is compressed by the first tube section, when the second shell is moved to the second position, the seal ring surrounds the second tube section and is uncompressed.

2. The joint of claim 1, wherein the second shell is further configured for connecting a plug connector, the folding mechanism unfolds to move the second shell to the first position, and the folding mechanism folds to move the second shell to the second position, when the second shell is moved to the first position, the plug connector is connected to a plug of a rack, when the second shell is moved to the second position, the plug connector is disconnected from the plug.

3. The joint of claim 2, wherein the folding mechanism comprises a switch located on the first shell, the switch is switchable between a first condition and a second condition, wherein when the switch is in the first condition, the folding mechanism is unfolded, the second shell is moved to the first position and the plug connector is connected to the plug, when the switch is in the second condition, the folding mechanism is folded, the second shell is moved to the second position and the plug connector is disconnected from the plug.

4. The joint of claim 3, wherein the folding mechanism further comprises a first folding piece and a second folding piece, the first folding piece is rotatably connected to the second folding piece, the first folding piece is rotatably connected to the first shell, the second folding piece is rotatably connected to the second shell, the folding mechanism unfolds by rotating the first folding piece and the second folding piece away from each other, and the folding mechanism folds by rotating the first folding piece and the second folding piece towards to each other.

5. The joint of claim 4, wherein the joint further comprises a spring, the spring is located between the first folding piece and the first shell, when the switch is in the first condition, the spring is compressed to keep the first folding piece and the second folding piece away from each other, when the switch is in the second condition, the spring is uncompressed and the first folding piece and the second folding piece is rotated by the spring towards to each other.

6. The joint of claim 5, wherein the first folding piece comprises a permanent magnet, the first condition of the switch is powered off, the second condition of the switch is powered on; when the switch is powered off, the switch attracts the permanent magnet to unfold the first folding piece and the second folding piece, when the switch is powered on, the switch is demagnetized and releases the permanent magnet, then the first folding piece and the second folding piece are folded by the spring.

7. The joint of claim 1, wherein the first shell further defines two sliding grooves, each of the second shell comprises two protrusions, each of the two protrusions is slidably placed in a respective sliding groove of the two sliding grooves to guide the second shell.

8. A server comprising:
a chassis;
a sensor located on the chassis and configured for sensing a leak of coolant; and
a joint located on the chassis, the joint comprising:
a first shell defining a tunnel and the first shell comprising a seal ring in the tunnel;
a second shell movably positioned on the first shell, the second shell comprising a first tube section and a second tube section; and
a folding mechanism connected to the first shell and the second shell, the folding mechanism configured for moving the second shell between a first position and a second position;
wherein the first tube section and the second tube section are movably inserted in the tunnel, an outer diameter of the first tube section is larger than an outer diameter of the second tube section; when the second shell is moved to the first position, the seal ring surrounds the first tube section and is compressed by the first tube section, when the second shell is moved to the second position, the seal ring surrounds the second tube section and is uncompressed.

9. The server of claim 8, wherein the second shell is further configured for connecting a plug connector, the folding mechanism unfolds to move the second shell to the first position, and the folding mechanism folds to move the second shell to the second position, when the second shell is moved to the first position, the plug connector is connected to a plug of a rack, when the second shell is moved to the second position, the plug connector is disconnected from the plug.

10. The server of claim 9, wherein the folding mechanism comprises a switch located on the first shell, the switch is switchable between a first condition and a second condition, wherein when the switch is in the first condition, the folding mechanism is unfolded, the second shell is moved to the first position and the plug connector is connected to the plug, when the switch is in the second condition, the folding mechanism is folded, the second shell is moved to the second position and the plug connector is disconnected from the plug.

11. The server of claim 10, wherein the folding mechanism further comprises a first folding piece and a second folding piece, the first folding piece is rotatably connected to the second folding piece, the first folding piece is rotatably connected to the first shell, the second folding piece is rotatably connected to the second shell, the folding mechanism unfolds by rotating the first folding piece and the second folding piece away from each other, and the folding mechanism folds by rotating the first folding piece and the second folding piece towards to each other.

12. The server of claim 11, wherein the joint further comprises a spring, the spring is located between the first folding piece and the first shell, when the switch is in the first condition, the spring is compressed to keep the first folding piece and the second folding piece away from each other, when the switch is in the second condition, the spring is uncompressed and the first folding piece and the second folding piece is rotated by the spring towards to each other.

13. The server of claim 12, wherein the first folding piece comprises a permanent magnet, the first condition of the switch is powered off, the second condition of the switch is powered on; when the switch is powered off, the switch attracts the permanent magnet to unfold the first folding piece and the second folding piece, when the switch is powered on, the switch is demagnetized and releases the permanent magnet, then the first folding piece and the second folding piece are folded by the spring.

14. The server of claim 8, wherein the first shell further defines two sliding grooves, each of the second shell comprises two protrusions, each of the two protrusions is slidably placed in a respective sliding groove of the two sliding grooves to guide the second shell.

15. A computing system comprising:
a rack comprising a plurality of plugs; and
a plurality of servers placed in the rack, each of the plurality of servers comprising:
a chassis;
a sensor configured for sensing a leak of coolant; and
a joint located on the chassis, the joint comprising:
a first shell defining a tunnel and the first shell comprising a seal ring in the tunnel;
a second shell movably positioned on the first shell, the second shell comprising a first tube section and a second tube section; and
a folding mechanism connected to the first shell and the second shell, the folding mechanism configured for moving the second shell between a first position and a second position;
wherein the first tube section and the second tube section are movably inserted in the tunnel, an outer diameter of the first tube section is larger than an outer diameter of the second tube section, when the second shell is moved to the first position, the seal ring surrounds the first tube section and is compressed by the first tube section, when the second shell is moved to the second position, the seal ring surrounds the second tube section and is uncompressed.

16. The computing system of claim 15, wherein the second shell is further configured for connecting a plug connector, the folding mechanism unfolds to move the second shell to the first position, and the folding mechanism folds to move the second shell to the second position, when the second shell is moved to the first position, the plug connector is connected to one of the plurality of plugs, when the second shell is moved to the second position, the plug connector is disconnected from the plug.

17. The computing system of claim 16, wherein the folding mechanism comprises a switch located on the first shell, the switch is switchable between a first condition and a second condition, wherein when the switch is in the first condition, the folding mechanism is unfolded, the second shell is moved to the first position and the plug connector is connected to the plug, when the switch is in the second condition, the folding mechanism is folded, the second shell is moved to the second position and the plug connector is disconnected from the plug.

18. The computing system of claim 17, wherein the folding mechanism further comprises a first folding piece and a second folding piece, the first folding piece is rotatably connected to the second folding piece, the first folding piece is rotatably connected to the first shell, the second folding piece is rotatably connected to the second shell, the folding mechanism unfolds by rotating the first folding piece and the second folding piece away from each other, and the folding mechanism folds by rotating the first folding piece and the second folding piece towards each other.

19. The computing system of claim 18, wherein the joint further comprises a spring, the spring is located between the first folding piece and the first shell, when the switch is in the first condition, the spring is compressed to keep the first folding piece and the second folding piece away from each other, when the switch is in the second condition, the spring is uncompressed and the first folding piece and the second folding piece is rotated by the spring towards to each other.

20. The computing system of claim 19, wherein the first folding piece comprises a permanent magnet, the first condition of the switch is powered off, the second condition of the switch is powered on; when the switch is powered off, the switch attracts the permanent magnet to unfold the first folding piece and the second folding piece, when the switch is powered on, the switch is demagnetized and releases the permanent magnet, then the first folding piece and the second folding piece are folded by the spring.
